(19) United States
(12) Patent Application Publication
(10) Pub. No.: US 2014/0273339 A1
(43) Pub. Date: Sep. 18, 2014

(54) Semiconductor Polymers

(71) Applicant: Saudi Basic Industries Corporation, Riyadh (SA)

(72) Inventors: Dwight Seferos, Mississauga (CA); Brandon Djukic, Toronto (CA); Amit Tevtia, Thuwal (SA)

(73) Assignee: SAUDI BASIC INDUSTRIES CORPORATION, Riyadh (SA)

(21) Appl. No.: 14/199,460

(22) Filed: Mar. 6, 2014

Related U.S. Application Data
(60) Provisional application No. 61/779,786, filed on Mar. 13, 2013.

(51) Int. Cl. H01L 51/00; H01L 51/56

(52) U.S. Cl. CPC H01L 51/0036; H01L 51/56
USPC 438/99; 528/8; 252/501.1; 526/239

(57) ABSTRACT

Disclosed is a semiconductor polymer having the following structure:

[chemical structure]

### CROSS REFERENCE TO RELATED APPLICATIONS

This application claims the benefit of U.S. Provisional Patent Application No. 61/779,786, filed Mar. 13, 2013. The contents of the referenced application are incorporated into the present application by reference.

### BACKGROUND OF THE INVENTION

A. Field of the Invention

The invention generally concerns the use of semi-conductive polymers that can be used in organic photovoltaic cells. In particular, the polymers of the present invention are n-type semi-conductive perylene bisimide based polymers that are linked together through a 1, 4 divinylbenezene linker.

B. Description of Related Art

Rising energy prices and concerns relating to global warming from burning fossil fuels has led to a search for more cost effective and efficient renewable energy sources. One such source of renewable energy that has been identified is solar energy. The problems associated with converting solar energy into electricity has been, in large part due to the inefficiencies of the energy conversion process. For instance, photovoltaic cells (e.g., solar cells) have been developed that can convert solar energy into usable energy, but the costs associated with doing so have hindered the widespread application of this technology into the marketplace.

In recent years research relating to the use of polymers in the photoactive layers of organic photovoltaic cells has increased. One of the unique aspects of using polymers is that they allow organic electronic devices to be manufactured by cost-effective solution-processing techniques such as spin casting, dip coating or ink jet printing. Solution processing can be carried out cheaper and on a larger scale compared to the evaporative techniques used to make inorganic thin film devices, which rely on vacuum deposition techniques.

However, many of the polymers that are currently being used suffer from low charge carrier mobility (electrical conduction), lower light absorption properties, and are complicated to synthesize. One of the solutions to this problem has been to shift from polymers to non-polymeric based n-type materials such as [6,6]-Phenyl C₇₁ butyric acid methyl ester (PC₇₁BM). PC₇₁BM is one of the most prevalent n-type materials used today in solar cell applications. It has the following general structure:

[chemical structure]

While this material is a sufficient n-type semiconductor, it is not a polymer and its light absorption and bandgap properties could be improved upon.

### SUMMARY OF THE INVENTION

It has been discovered that polymers made from perylene bisimide groups linked together with a 1, 4 divinylbenezene linker results in a n-type semiconductor polymer having improved light absorption and lower bandgap characteristics when compared with known n-type materials such as PC₇₁BM. Further, these polymers can be made through a scalable process that produces a high yield of the polymers. The polymers of the present invention can be used in the photoactive layer of an organic photovoltaic cell (e.g., the polymers can be used as n-type semi-conductive polymers).

In at least one aspect of the present invention there is disclosed a polymer that can be used in a photoactive layer in an organic photovoltaic cell having a structure of:

[chemical structure]

wherein
R₁ and R₂ are each independently selected from the group consisting of H, C₁₋₃₀-alkyl, C₂₋₃₀-alkenyl, C₂₋₃₀-alkynyl, C₃₋₁₀-cycloalkyl, C₅₋₁₀-cycloalkenyl, 3-14 membered cycloheteroalkyl, C₆₋₁₄-aryl and 5-14 membered heteroaryl,
R₃, R₄, R₉, and R₁₀ are each independently hydrogen, or —CN,
R₅, R₆, R₇, and R₈ are each independently hydrogen, a halogen selected from the group consisting of fluorine, chlorine, bromine iodine, and astatine, —CN, —NO₂, OH, —O—CH₂CH₂O—C₁₋₁₀-alkyl, —O—COX₁, —S—C₁₋₁₀-alkyl, —NH₂, NHX₁, —NX₁X₂, —NH—COX₁, —COOH, —COORS, —CONH₂, —CONHX₁, —CONX₁X₂, —CO—H, —COX₁, C₃₋₁₀-cycloalkyl, 3-14 membered cycloheteroalkyl, C₆₋₁₄-aryl or a 5-14 membered heteroaryl, with the proviso that neither of R₅, R₆, R₇, and R₈ are alkoxy groups (—OX₁) or at least three or all four of R₅, R₆, R₇, and R₈ are alkoxy groups,
   wherein
   X₁ and X₂ are each independently C₁₋₁₀-alkyl, C₂₋₁₀-alkenyl, C₂₋₁₀-alkynyl, C₃₋₁₀-cycloalkyl, C₅₋₁₀-cycloalkenyl, 3-14 membered cycloheteroalkyl, C₆₋₁₄-aryl and 5-14 membered heteroaryl, and
n is an integer greater than 2 or from 2 to 1000, or from 2 to 500, or from 2 to 100, or from 2 to 50, or from 2 to 25, or from 2 to 20, or from 2 to 15.

In certain aspects, R₁ and R₂ can each independently be hydrogen, branched or unbranched C₁₋₃₀-alkyl, C₂₋₃₀-alkenyl, or C₂₋₃₀-alkynyl. In other instances, R₁ and R₂ can each independently be hydrogen, branched or unbranched C₃₋₁₀-cycloalkyl, C₅₋₁₀-cycloalkenyl, or 3-14 membered cycloheteroalkyl. In still further embodiments, R₁ and R₂ can each independently be hydrogen, branched or unbranched C₆₋₁₄-aryl or 5-14 membered heteroaryl. Any of such groups can be un-substituted or substituted with 1 to 6 groups independently selected from halogen (e.g., fluorine, chlorine, bromine iodine, and astatine, —CN, —NO₂, —OH, C₁₋₁₀-alkoxy (e.g., methoxy, ethoxy, n-propoxy, isopropoxy, n-butoxy, sec-butoxy, isobutoxy, tert-butoxy, n-pentoxy, neopentoxy, isopentoxy, hexoxy, n-heptoxy, n-octoxy, n-nonoxy and n-decoxy), —O—CH₂CH₂O—C₁₋₁₀-alkyl, —O—COX₁, —S—C₁₋₁₀-alkyl, —NH₂, —NHX₁, —NX₁X₂, —NH—COX₁, —COOH, —COORS, —CONH₂, —CONHX₁, —CONX₁X₂, —CO—H, —COX₁, C₁₋₁₀-alkyl, C₂₋₁₀-alkenyl, C₂₋₁₀-alkynyl, C₃₋₁₀-cycloalkyl, 3-14 membered cycloheteroalkyl, C₆₋₁₄-aryl or a 5-14 membered heteroaryl, wherein X₁ and X₂ are each independently C₁₋₁₀-alkyl, C₂₋₁₀-alkenyl, C₂₋₁₀-alkynyl, C₃₋₁₀-cycloalkyl, C₅₋₁₀-cycloalkenyl, 3-14 membered cycloheteroalkyl, C₆₋₁₄-aryl or 5-14 membered heteroaryl.

Non-limiting examples of C₁₋₃₀-alkyl are C₁₋₁₀-alkyl, and n-undecyl, n-dodecyl, n-undecyl, n-dodecyl, n-tridecyl, n-tetradecyl, n-pentadecyl, n-hexadecyl, n-heptadecyl, n-octadecyl, n-nonadecyl and n-icosyl (C₂₀), n-docosyl (C₂₂), n-tetracosyl (C₂₄), n-hexacosyl (C₂₆), n-octacosyl (C₂₈) and n-triacontyl (C₃₀). Non-limiting examples of C₁₋₁₀-alkyl are methyl, ethyl, n-propyl, isopropyl, n-butyl, sec-butyl, isobutyl, tert-butyl, n-pentyl, neopentyl, isopentyl, n-(1-ethyl)propyl, n-hexyl, n-heptyl, n-octyl, n-(2-ethyl)hexyl, n-nonyl and n-decyl. Non-limiting examples of C₃₋₈-alkyl are n-propyl, isopropyl, n-butyl, sec-butyl, isobutyl, tert-butyl, n-pentyl, neopentyl, isopentyl, n-(1-ethyl)propyl, n-hexyl, n-heptyl, n-octyl and n-(2-ethyl)hexyl.

Non-limiting examples of C₂₋₃₀-alkenyl are C₂₋₁₀-alkenyl, linoleyl (C₁₈), linolenyl (C₁₈), oleyl (C₁₈), arachidonyl (C₂₀), and erucyl (C₂₂). Non-limiting examples of C₂₋₁₀-alkenyl are vinyl, propenyl, cis-2-butenyl, trans-2-butenyl, 3-butenyl, cis-2-pentenyl, trans-2-pentenyl, cis-3-pentenyl, trans-3-pentenyl, 4-pentenyl, 2-methyl-3-butenyl, hexenyl, heptenyl, octenyl, nonenyl and docenyl.

Non-limiting examples of C₂₋₃₀-alkynyl are C₂₋₁₀-alkynyl, undecynyl, dodecynyl, undecynyl, dodecynyl, tridecynyl, tetradecynyl, pentadecynyl, hexadecynyl, heptadecynyl, octadecynyl, non-adecynyl and icosynyl (C₂₀). Non-limiting examples of C₂₋₁₀-alkynyl are ethynyl, 2-propynyl, 2-butynyl, 3-butynyl, pentynyl, hexynyl, heptynyl, octynyl, nonynyl and decynyl.

Non-limiting examples of C₃₋₁₀-cycloalkyl are monocyclic C₃₋₁₀-cycloalkyls such as cyclopropyl, cyclobutyl, cyclopentyl, cyclohexyl, cycloheptyl and cyclooctyl, but include also polycyclic C₃₋₁₀-cycloalkyls such as decalinyl, norbornyl and adamantyl.

Non-limiting examples of C₅₋₁₀-cycloalkenyl include monocyclic C₅₋₁₀-cycloalkenyls such as cyclopentenyl, cyclohexenyl, cyclohexadienyl and cycloheptatrienyl, as well as polycyclic C₅₋₁₀-cycloalkenyls.

Non-limiting examples of 3-14 membered cycloheteroalkyl include monocyclic 3-8 membered cycloheteroalkyl and polycyclic (e.g., bicyclic 7-12 membered cycloheteroalkyl). Non-limiting examples of monocyclic 3-8 membered cycloheteroalkyl include monocyclic 5 membered cycloheteroalkyl containing one heteroatom such as pyrrolidinyl, 1-pyrrolinyl, 2-pyrrolinyl, 3-pyrrolinyl, tetrahydrofuryl, 2,3-dihydrofuryl, tetrahydrothiophenyl and 2,3-dihydrothiophenyl, monocyclic 5 membered cycloheteroalkyl containing two heteroatoms such as imidazolidinyl, imidazolinyl, pyrazolidinyl, pyrazolinyl, oxazolidinyl, oxazolinyl, isoxazolidinyl, isoxazolinyl, thiazolidinyl, thiazolinyl, isothiazolidinyl and isothiazolinyl, monocyclic 5 membered cycloheteroalkyl containing three heteroatoms such as 1,2,3-triazolyl, 1,2,4-triazolyl and 1,4,2-dithiazolyl, monocyclic 6 membered cycloheteroalkyl containing one heteroatom such as piperidyl, piperidino, tetrahydropyranyl, pyranyl, thianyl and thiopyranyl, monocyclic 6 membered cycloheteroalkyl containing two heteroatoms such as piperazinyl, morpholinyl and morpholino and thiazinyl, monocyclic 7 membered cycloheteroalkyl containing one hereoatom such as azepanyl, azepinyl, oxepanyl, thiepanyl, thiapanyl, thiepinyl, and monocyclic 7 membered cycloheteroalkyl containing two hereoatom such as 1,2-diazepinyl and 1,3-thiazepinyl. An example of a bicyclic 7-12 membered cycloheteroalkyl is decahydronaphthyl.

Non-limiting examples of C₆₋₁₄-aryl include both monocyclic or polycyclic aryls. Such examples include monocyclic C₆-aryl such as phenyl, bicyclic C₆₋₁₀-aryl such as 1-naphthyl, 2-naphthyl, indenyl, indanyl and tetrahydronaphthyl, and tricyclic C₁₂₋₁₄-aryl such as anthryl, phenanthryl, fluorenyl and s-indacenyl.

Non-limiting examples of 5-14 membered heteroaryl can be monocyclic 5-8 membered heteroaryl, or polycyclic 7-14 membered heteroaryl (e.g., bicyclic 7-12 membered or tricyclic 9-14 membered heteroaryl). Examples of monocyclic 5-8 membered heteroaryl include monocyclic 5 membered heteroaryl containing one heteroatom such as pyrrolyl, furyl and thiophenyl, monocyclic 5 membered heteroaryl containing two heteroatoms such as imidazolyl, pyrazolyl, oxazolyl, isoxazolyl, thiazolyl, isothiazolyl, monocyclic 5 membered heteroaryl containing three heteroatoms such as 1,2,3-triazolyl, 1,2,4-triazolyl and oxadiazolyl, monocyclic 5 membered heteroaryl containing four heteroatoms such as tetrazolyl, monocyclic 6 membered heteroaryl containing one heteroatom such as pyridyl, monocyclic 6 membered heteroaryl containing two heteroatoms such as pyrazinyl, pyrimidinyl and pyridazinyl, monocyclic 6 membered heteroaryl containing three heteroatoms such as 1,2,3-triazinyl, 1,2,4-triazinyl and 1,3,5-triazinyl, monocyclic 7 membered heteroaryl containing one heteroatom such as azepinyl, and monocyclic 7 membered heteroaryl containing two heteroatoms such as 1,2-diazepinyl. Examples of bicyclic 7-12 membered heteroaryl are bicyclic 9 membered heteroaryl containing one heteroatom such as indolyl, isoindolyl, indolizinyl, indolinyl, benzofuryl, isobenzofuryl, benzothiophenyl and isobenzothiophenyl, bicyclic 9 membered heteroaryl containing two heteroatoms such as indazolyl, benzimidazolyl, benzimidazolinyl, benzoxazolyl, benzisooxazolyl, benzthiazolyl, benzisothiazolyl, furopyridyl and thienopyridyl, bicyclic 9 membered heteroaryl containing three heteroatoms such as benzotriazolyl, benzoxadiazolyl, oxazolopyridyl, isooxazolopyridyl, thiazolopyridyl, isothiazolopyridyl and imidazopyridyl, bicyclic 9 membered heteroaryl containing four heteroatoms such as purinyl, bicyclic 10 membered heteroaryl containing one heteroatom such as quinolyl, isoquinolyl, chromenyl and chromanyl, bicyclic 10 membered heteroaryl containing two heteroatoms such as quinoxalinyl, quinazolinyl, cinnolinyl, phthalazinyl, 1,5-naphthyridinyl and 1,8-naphthyridinyl, bicyclic 10 membered heteroaryl containing three heteroatoms such as pyridopyrazinyl, pyridopyrimidinyl and pyridopyridazinyl, and bicyclic 10 membered heteroaryl containing four heteroatoms such as pteridinyl. Examples of tricyclic 9-14 membered heteroaryls are dibenzofuryl, acridinyl, phenoxazinyl, 7H-cyclopenta[1,2-b:3,4-b′]dithiophenyl and 4H-cyclopenta[2,1-b:3,4-b′]dithiophenyl.

In particular instances, R₁ and R₂ can be 2-ethylhexyl, 2-octyldodecyl, or 2-decyltetradecyl. In one instance R₁ and R₂ are both branched alkyl groups having the following formula:

[chemical structure]

Further, each of R₃, R₄, R₉, and R₁₀ can be hydrogen and each of R₅, R₆, R₇, and R₈ can be hydrogen in this embodiment.

The polymers of the present invention can be the reaction product of formula (I) with formula (II):

[chemical structure]

wherein, R₁₁ is a halogen selected from the group consisting of fluorine, chlorine, bromine iodine, and astatine, and
R₁₂ and R₁₃ are each independently a linking group.
   The linking group can be a substituted or un-substituted C₂₋₆alkyl or C₂₋₆alkylene group. Examples of C₂₋₆alkyl groups include n-propyl, isopropyl, n-butyl, sec-butyl, isobutyl, tert-butyl, n-pentyl, neopentyl, isopentyl, n-(1-ethyl)propyl, n-hexyl or hexane, 2-methylpentane, 3-methylpentane, 2,3-dimethylbutane, and 2,2-dimethylbutane. Examples of C₂₋₆alkylene groups include ethylene, propylene, butylene, pentylene, or hexylene. In particular instances, the linker can be 2,3-dimethylbutane. In a further, aspect, the polymers of the present invention can be prepared by reacting formula (I) with formula (II) in the presence of a transition metal-containing catalyst (e.g., Pd(PPh₃)₄). The process can further include mixing or combining formula (I), formula (II), and the transition metal-containing catalyst are mixed together to form a mixture and heating the mixture (e.g., 50, 60, 70, 80, 90 or up to 100° C. or more) for a sufficient period of time (e.g., 1, 2, 3, 4, 5, 6, 7, 8, 9, 15, 20, or up to 24 hours or more) to produce the polymer. The mixture can further include a solvent such as those disclosed in the specification (two non-limiting examples include THF and chloroform).

Also disclosed is an organic photovoltaic cell that includes a photoactive layer or layers. The photoactive layer or layers can include any one of the polymers of the present invention. The photovoltaic cell can include a transparent or translucent substrate, a transparent or translucent electrode, the photoactive layer or layers, and a second electrode. The photoactive layer or layer can be disposed between the transparent/translucent electrode and the second electrode. The transparent/translucent electrode can be a cathode and the second electrode can be an anode or the transparent/translucent electrode can be an anode and the second electrode can be a cathode. In certain instances, the second electrode is opaque/not-transparent. The photovoltaic cell can be a bulk heterojunction photovoltaic cell or a bi-layer photovoltaic cell for example.

In another embodiment, there is disclosed an organic electronic device that includes any one of the photovoltaic cells or polymers of the present invention. Non-limiting examples of organic electronic devices include polymeric organic light-emitting diodes (PLEDs), organic integrated circuits (O-ICs), organic field effect transistors (OFETs), organic thin film transistors (OTFTs), organic solar cells (O-SCs), organic light emitting diode (OLED), or organic laser diodes (O-lasers).

In yet another embodiment, there is disclosed a photoactive layer that includes at least one of the polymers of the present invention. The photoactive layer can be included in a photovoltaic cell or in an organic electronic device. The photoactive layer can include additional materials such as p-type materials (e.g., polymers or small molecules).

In still another aspect of the present invention there is disclosed a solution comprising any one of the polymers of the invention dissolved in said solution. The solvent used can be one that effectively solubilizes the polymer. Non-limiting examples of solvents include toluene, xylene, tetralin, decalin, mesitylene, n-butylbenzene, sec-butylbutylbenzene, and tert-butylbenzene; halogenated aromatic hydrocarbon-based solvents such as chlorobenzene, dichlorobenzene, and trichlorobenzene, halogenated saturated hydrocarbon-based solvents such as carbon tetrachloride, chloroform, dichloromethane, dichloroethane, chlorobutane, bromobutane, chloropentane, chlorohexane, bromohexane, and chlorocyclohexane, and ethers such as tetrahydrofuran and tetrahydropyran. The solution can be deposited by doctor blade coating, spin coating, meniscus coating, transfer printing, ink jet printing, offset printing, screen printing process, dip coating, casting, bar coating, roll coating, wire bar coating, spraying, screen printing, gravure printing, flexo printing, offset printing, gravure offset printing, dispenser coating, nozzle coating, capillary coating, etc.

Also disclosed are Embodiments 1 to 38 of the present invention. Embodiment 1 is a polymer having a structure of:

[chemical structure]

wherein R₁ and R₂ are each independently selected from the group consisting of H, C₁₋₃₀-alkyl, C₂₋₃₀-alkenyl, C₂₋₃₀-alkynyl, C₃₋₁₀-cycloalkyl, C₅₋₁₀-cycloalkenyl, 3-14 membered cycloheteroalkyl, C₆₋₁₄-aryl and 5-14 membered heteroaryl, R₃, R₄, R₉, and R₁₀ are each independently hydrogen, or —CN, R₅, R₆, R₇, and R₈ are each independently hydrogen, a halogen selected from the group consisting of fluorine, chlorine, bromine iodine, and astatine, —CN, —NO₂, —OH, —O—CH₂CH₂O—C₁₋₁₀-alkyl, —O—COX₁, —S—C₁₋₁₀-alkyl, —NH₂, NHX₁, —NX₁X₂, —NH—COX₁, —COOH, —COORS, —CONH₂, —CONHX₁, —CONX₁X₂, —CO—H, —COX₁, C₃₋₁₀-cycloalkyl, 3-14 membered cycloheteroalkyl, C₆₋₁₄-aryl or a 5-14 membered heteroaryl, with the proviso that neither of R₅, R₆, R₇, and R₈ are alkoxy groups (—OX₁) or at least three or all four of R₅, R₆, R₇, and R₈ are alkoxy groups, wherein X₁ and X₂ are each independently C₁₋₁₀-alkyl, C₂₋₁₀-alkenyl, C₂₋₁₀-alkynyl, C₃₋₁₀-cycloalkyl, C₅₋₁₀-cycloalkenyl, 3-14 membered cycloheteroalkyl, C₆₋₁₄-aryl and 5-14 membered heteroaryl, and n is an integer from 2 to 1000. Embodiment 2 is the polymer of Embodiment 1, wherein R₁ and R₂ are each independently C₁₋₃₀-alkyl, C₂₋₃₀-alkenyl or C₂₋₃₀-alkynyl. Embodiment 3 is the polymer of Embodiment 2, wherein C₁₋₃₀-alkyl, C₂₋₃₀-alkenyl or C₂₋₃₀-alkynyl are substituted with 1 to 6 groups independently selected from halogen, —CN, —NO₂, —OH, C₁₋₁₀-alkoxy, —O—CH₂CH₂O—C₁₋₁₀-alkyl, —O—COX₁, —S—C₁₋₁₀-alkyl, —NH₂, —NHX₁, —NX₁X₂, —NH—COX₁, —COOH, —COORS, —CONH₂, —CONHX₁, —CONX₁X₂, —CO—H, —COX₁, C₃₋₁₀-cycloalkyl, 3-14 membered cycloheteroalkyl, C₆₋₁₄-aryl or a 5-14 membered heteroaryl, wherein X₁ and X₂ are each independently C₁₋₁₀-alkyl, C₂₋₁₀-alkenyl, C₂₋₁₀-alkynyl, C₃₋₁₀-cycloalkyl, C₅₋₁₀-cycloalkenyl, 3-14 membered cycloheteroalkyl, C₆₋₁₄-aryl and 5-14 membered heteroaryl. Embodiment 4 is the polymer of Embodiment 1, wherein R₁ and R₂ are each independently C₃₋₁₀-cycloalkyl, C₅₋₁₀-cycloalkenyl, or 3-14 membered cycloheteroalkyl. Embodiment 5 is the polymer of Embodiment 4, wherein C₃₋₁₀-cycloalkyl, C₅₋₁₀-cycloalkenyl, or 3-14 membered cycloheteroalkyl are substituted with 1 to 6 groups independently selected from halogen, —CN, —NO₂, —OH, C₁₋₁₀-alkoxy, —O—CH₂CH₂O—C₁₋₁₀-alkyl, —O—COR₇, —S—C₁₋₁₀-alkyl, —NH₂, —NHX₁, —NX₁X₂, —NH—COX₁, —COOH, —COORS, —CONH₂, —CONHX₁, CONX₁X₂, —CO—H, —COX₁, C₁₋₁₀-alkyl, C₂₋₁₀-alkenyl, C₂₋₁₀-alkynyl, C₆₋₁₄-aryl or a 5-14 membered heteroaryl, wherein X₁ and X₂ are each independently C₁₋₁₀-alkyl, C₂₋₁₀-alkenyl, C₂₋₁₀-alkynyl, C₃₋₁₀-cycloalkyl, C₅₋₁₀-cycloalkenyl, 3-14 membered cycloheteroalkyl, C₆₋₁₄-aryl and 5-14 membered heteroaryl. Embodiment 6 is the polymer of Embodiment 1, wherein R₁ and R₂ are each independently C₆₋₁₄-aryl or 5-14 membered heteroaryl. Embodiment 7 is the polymer of Embodiment 6, wherein, C₆₋₁₄-aryl or 5-14 membered heteroaryl are substituted with 1 to 6 groups independently selected from the group consisting of halogen, —CN, —NO₂, —OH, C₁₋₁₀-alkoxy, —O—CH₂CH₂O—C₁₋₁₀-alkyl, —O—COX₁, —S—C₁₋₁₀-alkyl, —NH₂, —NHX₁, NX₁X₂, —NH—COX₁, —COOH, —COORS, —CONH₂, —CONHX₁, —CONX₁X₂, —CO—H, —COX₁, C₁₋₁₀-alkyl, C₂₋₁₀-alkenyl, C₂₋₁₀-alkynyl, C₃₋₁₀-cycloalkyl, C₅₋₁₀-cycloalkenyl or a 3-14 membered cycloheteroalkyl, wherein X₁ and X₂ are each independently C₁₋₁₀-alkyl, C₂₋₁₀-alkenyl, C₂₋₁₀-alkynyl, C₃₋₁₀-cycloalkyl, C₅₋₁₀-cycloalkenyl, 3-14 membered cycloheteroalkyl, C₆₋₁₄-aryl and 5-14 membered heteroaryl. Embodiment 8 is the polymer of Embodiment 1, wherein R₁ and R₂ are both branched alkyl groups selected from the group consisting of 2-ethylhexyl, 2-octyldodecyl, or 2-decyltetradecyl or wherein R₁ and R₂ are both branched alkyl groups having the following formula:

[chemical structure]

Embodiment 9 is the polymer of Embodiment 8, wherein each of R₃, R₄, R₉, and R₁₀ are each hydrogen. Embodiment 10 is the polymer of any one of Embodiment 1 to 8, wherein each of R₅, R₆, R₇, and R₈ are each hydrogen. Embodiment 11 is the polymer of any one of Embodiments 1 to 10, wherein n is an integer from 2 to 100. Embodiment 12 is the polymer of Embodiment 11, wherein n is an integer from 2 to 20. Embodiment 13 is the polymer of any one of Embodiments 1 to 12, wherein the polymer is an n-type semi-conductive polymer. Embodiment 14 is the polymer of Embodiment 13, wherein the polymer is modified with a dopant so as to enhance its n-type properties. Embodiment 15 is the polymer of any one of Embodiments 1 to 14, wherein the polymer is the reaction product of formula (I) with formula (II):

[chemical structure]

wherein R₁₁ is a halogen selected from the group consisting of fluorine, chlorine, bromine iodine, and astatine, and R₁₂ and R₁₃ are each independently a linking group. Embodiment 16 is the polymer of Embodiment 15, wherein the linking group is a C₂₋₆alkyl or alkylene group. Embodiment 17 is the polymer of Embodiment 16, wherein the linking group is 2,3-dimethylbutane. Embodiment 18 is a photovoltaic cell comprising a photoactive layer comprising a polymer of any one of Embodiments 1 to 16. Embodiment 19 is the photovoltaic cell of Embodiment 18, comprising a transparent substrate, a transparent electrode, the photoactive layer, and a second electrode, wherein the photoactive layer is disposed between the transparent electrode and the second electrode. Embodiment 20 is the photovoltaic cell of Embodiment 19, wherein the transparent electrode is a cathode and the second electrode is an anode. Embodiment 21 is the photovoltaic cell of Embodiment 19, wherein the transparent electrode is an anode and the second electrode is a cathode. Embodiment 22 is the photovoltaic cell of any one Embodiments 18 to 21, wherein the second electrode is not transparent. Embodiment 23 is the photovoltaic cell of any one of Embodiments 18 to 22, wherein photovoltaic cell is a bulk heterojunction photovoltaic cell. Embodiment 24 is the photovoltaic cell of any one of Embodiments 18 to 22, wherein photovoltaic cell is a bi-layer photovoltaic cell. Embodiment 25 is the photovoltaic cell of any one of Embodiments 18 to 24, wherein the photovoltaic cell is comprised in an organic electronic device. Embodiment 26 is the photovoltaic cell of Embodiment 25, wherein the organic electronic device is a polymeric organic light-emitting diode (PLED), an organic integrated circuit (O-IC), an organic field effect transistor (OFET), an organic thin film transistor (OTFT), an organic solar cell (O-SC) or an organic laser diode (O-laser). Embodiment 27 is the photovoltaic cell of any one of Embodiments 18 to 26, further comprising a p-type semi-conductive material. Embodiment 28 is the photovoltaic cell of Embodiment 27, wherein the p-type semi-conductive material is a polymer or a small molecule. Embodiment 29 is a solution comprising any one of the polymers of Embodiments 1 to 17, wherein the polymer is dissolved in said solution. Embodiment 30 is a process for making a photoactive layer on a substrate, wherein the photoactive layer comprises any one of the polymers of Embodiments 1 to 17, the process comprising disposing the solution of claim 28 on the substrate and drying said solution to form the photoactive layer. Embodiment 31 is the process of Embodiment 30, wherein the solution is disposed on the substrate layer by a doctor blade coating, spin coating, meniscus coating, transfer printing, ink jet printing, offset printing or screen printing process. Embodiment 32 is a process of making any one of the polymers of claims 1 to 17 comprising reacting formula (I) with formula (II) in the presence of a transition metal-containing catalyst, wherein formula (I) and formula (II) have the following structures:

[chemical structure]

Embodiment 33 is the process of Embodiment 32, wherein formula (I), formula (II), and the transition metal-containing catalyst are mixed together to form a mixture, wherein the mixture is heated, and wherein the polymer of any one of Embodiments 1 to 17 is produced. Embodiment 34 is the process of Embodiment 33, wherein the mixture further comprises a solvent that solubilizes formulas (I) and (II). Embodiment 35 is the process of Embodiment 34, wherein the solvent is THF or chloroform. Embodiment 36 is the process of any one of Embodiments 32 to 35, wherein the transition metal-containing catalyst is Pd(PPh₃)₄. Embodiment 37 is an electronic device comprising any one of the polymers of Embodiments 1 to 17. Embodiment 38 is the electronic device of Embodiment 37, wherein the electronic device is a polymeric organic light-emitting diode (PLED), an organic integrated circuits (O-IC), an organic field effect transistor (OFET), an organic thin film transistor (OTFT), an organic solar cell (O-SC), an organic light emitting diode (OLED), or an organic laser diode (O-laser).

The term “about” or “approximately” are defined as being close to as understood by one of ordinary skill in the art, and in one non-limiting embodiment the terms are defined to be within 10%, preferably within 5%, more preferably within 1%, and most preferably within 0.5%.

The use of the word “a” or “an” when used in conjunction with the term “comprising” in the claims or the specification may mean “one,” but it is also consistent with the meaning of “one or more,” “at least one,” and “one or more than one.”

The words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The polymers, photoactive layers, photovoltaic cells, and organic electronic devices of the present invention can “comprise,” “consist essentially of,” or “consist of” particular ingredients, components, compositions, etc. disclosed throughout the specification. With respect to the transitional phase “consisting essentially of,” in one non-limiting aspect, a basic and novel characteristic of the polymers of the present invention are their n-type semi-conductive properties.

Other objects, features and advantages of the present invention will become apparent from the following figures, detailed description, and examples. It should be understood, however, that the figures, detailed description, and examples, while indicating specific embodiments of the invention, are given by way of illustration only and are not meant to be limiting. Additionally, it is contemplated that changes and modifications within the spirit and scope of the invention will become apparent to those skilled in the art from this detailed description.

### BRIEF DESCRIPTION OF THE DRAWINGS

FIG. 1: Illustration of an organic photovoltaic cell incorporating the polymers of the present invention.

FIG. 2: ¹H-NMR of a polymer of the present invention.

FIG. 3: Thin film absorbance profile of a polymer of the present invention.

FIG. 4: Cyclic voltammogram of a polymer of the present invention.

FIG. 5: HOMO-LUMO energy levels for a polymer of the present invention and PC₇₁BM.

### DETAILED DESCRIPTION OF THE INVENTION

A new semiconductor polymer has been discovered that addresses the drawbacks from current organic materials that are used in photovoltaic cells. These and other non-limiting aspects of the present invention are discussed in further detail in the following sections.

### A. Semiconductor Polymers

The semi-conductive polymers of the present invention are based on repeating monomeric units of perylene bisimide. The general structure of an un-substituted perylene bisimide is:

[chemical structure]

It was discovered that p-vinylstyrene (or 1, 4 divinylbenzene) can be used as a linker to polymerize the perylene bisimide monomeric units, while creating a stable and effective n-type semi-conductive polymer of the present invention. p-vinylstyrene has the general structure:

[chemical structure]

In one non-limiting aspect, the polymers can be prepared by using the following compounds (1) and (2):

[chemical structure]

Compound (1) can be obtained by reacting p-vinylstyrene with a boron containing linking group using the Heck cross-coupling technique (see Dadvand, A., Moiseev, A. G., Sawabe, K., Sun, W.-H., Djukic, B., Chung, I., Takenobu, T., Rosei, F. and Perepichka, D. F. (2012), Maximizing Field-Effect Mobility and Solid-State Luminescence in Organic Semiconductors. Angew. Chem. Int. Ed., 51: 3837-3841. doi: 10.1002/anie.201108184, which is incorporated by reference). Compound (2) was prepared from perylene-3,4,9,10-tetracarboxylic dianhydride following a similar literature procedure (Huo, L., Zhou, Y. and Li, Y. (2008), Synthesis and Absorption Spectra of n-Type Conjugated Polymers Based on Perylene Diimide. Macromol. Rapid Commun., 29: 1444-1448. doi: 10.1002/marc.200800268, which is incorporated by reference). Compounds (1) and (2) can then be reacted together using the Suzuki cross-coupling technique (see Zhou, E., Cong, J., Wei, Q., Tajima, K., Yang, C. and Hashimoto, K. (2011), All-Polymer Solar Cells from Perylene Diimide Based Copolymers: Material Design and Phase Separation Control. Angew. Chem. Int. Ed., 50: 2799-2803. doi: 10.1002/anie.201005408, which is incorporated by reference) to prepare a particular polymer of the present invention (P-2). The following reaction scheme 1 can be used:

[chemical structure]

As explained in other sections of the present invention (e.g., summary of the invention and claims), which are incorporated by reference, additional polymers having various R groups can be prepared using the above reaction scheme. By way of example, the following generic reaction scheme 2 can be used, with the R groups being those as previously defined:

[chemical structure]

### B. Organic Photovoltaic Cells

The semi-conductive polymers of the present invention can be used in organic photovoltaic cells. FIG. 1 is a cross-sectional view of a non-limiting organic photovoltaic cell that the polymers of the present invention can be incorporated into. The organic photovoltaic cell (1) can include a transparent substrate (10), a front electrode (11), a photoactive layer (12), and a back electrode (13). Additional materials, layers, and coatings (not shown) known to those of ordinary skill in the art can be used with photovoltaic cell (1), some of which are described below.

Generally speaking, the organic photovoltaic cell (1) can convert light into usable energy by: (a) photon absorption to produce excitons; (b) exciton diffusion; (c) charge transfer; and (d) charge-transportation to the electrodes. With respect to (a), the excitons are produced by photon absorption by the photoactive layer (12), which can be a mixture of p-type and n-type organic semiconductor materials (e.g., bulk heterojunction) or which can be separate p-type and n-type layers adjacent to one another (i.e., bi-layer heterojunction). For (b), the generated excitons diffuse to the p-n junction. Then in (c), the excitons separate into electrons and holes. For (d), electrons and holes are transported to the electrodes (11) and (13) and are used in a circuit.

1. Substrate (10)

The substrate (10) can be used as support. For organic photovoltaic cells, it is typically transparent or translucent, which allows light to efficiently enter the cell. It is typically made from material that is not easily altered or degraded by heat or organic solvents, and as already noted, has excellent optical transparency. Non-limiting examples of such materials include inorganic materials such as alkali-free glass and quartz glass, polymers such as polyethylene, polyethylene terephthalate, polyethylene naphthalate, polyimide, polyamide, polyetherimide, polyamidoimide, liquid crystal polymer, and cycloolefin polymer, silicon, and metal.

2. Front Electrode and Back Electrodes (11) and (13)

The front electrode (11) can be used as a cathode or anode depending on the set-up of the circuit. It is stacked on the substrate (10). The front electrode (11) is made of a transparent or translucent conductive material. Typically, the front electrode (11) is obtained by forming a film using such a material (e.g., vacuum deposition, sputtering, ion-plating, plating, coating, etc.). Non-limiting examples of transparent or translucent conductive material include metal oxide films, metal films, and conductive polymers. Non-limiting examples of metal oxides that can be used to form a film include indium oxide, zinc oxide, tin oxide, and their complexes such as indium-doped tin oxide (ITO), fluorine-doped tin oxide (FTO), and indium zinc oxide films. Non-limiting examples of metals that can be used to form a film include gold, platinum, silver, and copper. Non-limiting examples of conductive polymers include polyaniline and polythiophene. The thickness of the film for the front electrode (11) is typically between from 30 to 300 nm. If the film thickness is less than 30 nm, then the conductivity can be reduced and the resistance increased, which results in a decrease in photoelectric conversion efficiency. If the film thickness is greater than 300 nm, then light transmittance may be lowered. Also, the sheet resistance of the front electrode (11) is typically 10Ω/□ or less. Further, the front electrode (11) may be a single layer or laminated layers formed of materials each having a different work function.

The back electrode (13) can be used as a cathode or anode depending on the set-up of the circuit. This electrode (13) can be stacked on the photoactive layer (12). The material used for the back electrode (13) is conductive. Non-limiting examples of such materials include metals, metal oxides, and conductive polymers (e.g., polyaniline, polythiophene, etc.) such as those discussed above in the context of the front electrode (11). When the front electrode (11) is formed using a material having high work function, then the back electrode (13) can be made of material having a low work function. Non-limiting examples of materials having a low work function include Li, In, Al, Ca, Mg, Sm, Tb, Yb, Zr, Na, K, Rb, Cs, Ba, and the alloys thereof. The back electrode (13) can be a single layer or laminated layers formed of materials each having a different work function. Further, it may be an alloy of one or more of the materials having a low work function and at least one selected from the group consisting of gold, silver, platinum, copper, manganese, titanium, cobalt, nickel, tungsten, and tin. Examples of the alloy include a lithium-aluminum alloy, a lithium-magnesium alloy, a lithium-indium alloy, a magnesium-silver alloy, a magnesium-indium alloy, a magnesium-aluminium alloy, an indium-silver alloy, and a calcium-aluminum alloy. The film thickness of the back electrode (13) can be from 1 to 1000 nm or from 10 to 500 nm. If the film thickness is too small, then the resistance can be excessively large and the generated charge may not be sufficiently transmitted to the external circuit.

In some embodiments, the front (11) and back (13) electrodes can be further coated with hole transport or electron transport layers (not shown in FIG. 1) to increase the efficiency and prevent short circuits of the organic photovoltaic cell (1). The hole transport layer and the electron transport layer can be interposed between the electrode and the photoactive layer (12). Non-limiting examples of the materials that can be used for the hole transport layer include polythiophene-based polymers such as PEDOT/PSS (poly(3,4-ethylenedioxythiophene)-poly(styrene sulfonate)) and organic conductive polymers such as polyaniline and polypyrrole. The film thickness of the hole transport layer can be from 20 to 100 nm. If the film thickness is too thin, short circuit of the electrode can occur more readily. If the film thickness is too thick, the film resistance is large and the generated electric current could be limited and optical conversion efficiency can be reduced. As for the electron transport layer, it can function by blocking holes and transporting electrons more efficiently. Non-limiting examples of the type of material that the electron transport layer can be made of include metal oxides (e.g., amorphous titanium oxide). When titanium oxide is used, the film thickness can range from 5 to 20 nm. If the film thickness is too thin, the hole blocking effect can be reduced and thus the generated excitons are deactivated before the excitons dissociate into electrons and holes. By comparison, when the film thickness is too thick, the film resistance is large, the generated electric current is limited, resulting in reduction of optical conversion efficiency.

3. Photoactive Layer (12)

The photoactive layer (12) can be interposed between the front electrode (10) and the back electrode (13). In one instance, the photoactive layer (12) can be a bulk hetero-junction type layer such that the polymers of the present invention are mixed with a second semi-conductive material (e.g., a second polymer or a small molecule) and a micro phase separation occurs within said layer (12). Alternatively, the photoactive layer (12) can be a bi-layer hetero-junction type layer such that the polymers of the present invention form one layer and a second photoactive layer is adjacent thereto. In either instance, the layer (12) will include both p-type and n-type organic semiconductors, thereby allowing for the flow of electrons. Further, there can be multiple photoactive layers used for a given photovoltaic cell (e.g., 2, 3, 4, or more). As the polymers of the present invention are n-type polymers, p-type materials can be added such as p-type polymers and p-type small molecules, both of which are known to those of skill in the art. Non-limiting examples of such materials include poly(phenylene-vinylene)s, poly-3-alkylthiophenes, pentacene, and copper phthalocyanine.

The photoactive layer can be deposited by obtaining a solution that includes a solvent and the polymers of the present invention solubilized therein. Non-limiting examples of such solvents include unsaturated hydrocarbon-based solvents such as toluene, xylene, tetralin, decalin, mesitylene, n-butylbenzene, sec-butylbutylbenzene, and tert-butylbenzene; halogenated aromatic hydrocarbon-based solvents such as chlorobenzene, dichlorobenzene, and trichlorobenzene, halogenated saturated hydrocarbon-based solvents such as carbon tetrachloride, chloroform, dichloromethane, dichloroethane, chlorobutane, bromobutane, chloropentane, chlorohexane, bromohexane, and chlorocyclohexane, and ethers such as tetrahydrofuran and tetrahydropyran. The solution can be deposited by doctor blade coating, spin coating, meniscus coating, transfer printing, ink jet printing, offset printing, screen printing process, dip coating, casting, bar coating, roll coating, wire bar coating, spraying, screen printing, gravure printing, flexo printing, offset printing, gravure offset printing, dispenser coating, nozzle coating, capillary coating, etc.

### EXAMPLES

The present invention will be described in greater detail by way of specific examples. The following examples are offered for illustrative purposes only, and are not intended to limit the invention in any manner. Those of skill in the art will readily recognize a variety of noncritical parameters which can be changed or modified to yield essentially the same results.

### Example 1

### Synthesis of P-2 With Reaction Scheme 1

Synthesis of P-2 Using Reaction Scheme 1: A mixture of Pd(PPh₃)₄ (3.8 mg, 0.00329 mmol), 2.0 M Na₂CO_{3(aq)} (3.79 mL), 1,4-bis((E)-2-(4,4,5,5-tetramethyl-1,3,2-dioxaborolan-2-yl)vinyl)benzene 1 (30 mg, 0.0785 mmol) (prepared by Heck coupling of 1,4-diiodobenzene in quantitative yield. The spectroscopic properties were identical to those previously reported (see T. Lee, C. Baik, I. Jung, K. H. Song, S. Kim, D. Kim, S. O. Kang, and J. Ko, Organometallics 2004, 23, 4569), and PDI monomer 2 (96 mg, 0.0786 mmol) was stirred in THF (6.28 mL) at 90° C. under an argon atmosphere. The reaction proceeded for 24 h, at which point additional Pd(PPh₃)₄ (8.0 mg, 0.00693 mmol) and argon sparged THF (5.00 mL) were added. The reaction continued for another 24 h. After cooling to room temperature the mixture was combined with water (100 mL). The precipitate was separated by filtration and washed with distilled water and then purified by Soxhlet extraction using methanol, hexanes and THF. The THF fraction was concentrated to give P-2 as a dark purple solid (55 mg, 60%). P-2 synthesized under these conditions had a M_{w}=9.9 kDa, Mₙ=5.6 kDa and Mn/Mw=1.77. FIG. 2 shows ¹H-NMR (400 MHz, CDCl₃): δ 8.66 (m, 6H), 7.68 (m, 8H), 4.15 (br, 4H), 2.02 (br, 2H), 1.48-1.03 (m, 80H), 0.78 (br, 12H). Mₙ=5600 Da, PDI=1.77. The absorbance profile of P-2 was analyzed as a thin film, obtained by spin coating the polymer onto a glass surface. P-2 is a strong light absorber within the visible spectrum, with an absorbance onset at around 709 nm and a maxima at 389 and 550 nm (FIG. 3). The electrochemical properties of P-2 were analyzed as a thin film, obtained by spin coating the polymer onto an ITO surface. Electrochemical analysis confirms that P-2 is a stable electron acceptor (FIG. 4).

### Example 2

### HOMO and LUMO Analysis

A thin film of polymer P-2 was spin-coated on to the surface of an ITO electrode and studied in a 0.1 M N(C₄H₉)₄ PF₆ acetonitrile solution. A reversible reduction with an onset at −1.11 V (vs. fc/fc⁺) was observed, in addition to an oxidation with an onset at 0.67 V. The oxidation and reduction values obtained correspond to HOMO and LUMO levels of −5.50 eV and −3.79 eV respectively, with a HOMO-LUMO gap of 1.78 eV. P-2 is an excellent candidate for solar cell materials. By comparison to PC₇₁BM, one of the most prevalent n-type solar cell materials already commercially available, P-2 has a lower band gap and absorbs light more strongly across the visible spectrum (see Table 1) (FIG. 5). Furthermore P-2 is highly soluble in common organic solvents such as THF or chloroform, and is solution processable.

TABLE 1
(Competitive analysis between P-2 and PC₇₁BM)

| Material | P-2 | PC₇₁BM* |
|---|---|---|
| LUMO | −3.79 | −3.9 |
| HOMO | −5.57 | −6.00 |
| Gap | 1.78 | 2.10 |
| E (M⁻¹cm⁻¹) | 41,000 (389 nm) | 18,000 (400 nm) |
| | 24,000 (550 nm) | 2,000 (650 nm) |

*Data for PC₇₁BM was obtained from Sigma-Aldrich ® webpage
http://www.sigmaaldrich.com/catalog/product/aldrich/684465?lang=en&region=US.

1. A polymer having a structure of: [chemical structure]
wherein
R₁ and R₂ are each independently selected from the group consisting of H, C₁₋₃₀-alkyl, C₂₋₃₀-alkenyl, C₂₋₃₀-alkynyl, C₃₋₁₀-cycloalkyl, C₅₋₁₀-cycloalkenyl, 3-14 membered cycloheteroalkyl, C₆₋₁₄-aryl and 5-14 membered heteroaryl,
R₃, R₄, R₉, and R₁₀ are each independently hydrogen, or —CN,
R₅, R₆, R₇, and R₈ are each independently hydrogen, a halogen selected from the group consisting of fluorine, chlorine, bromine iodine, and astatine, —CN, —NO₂, —OH, —O—CH₂CH₂O—C₁₋₁₀-alkyl, —O—COX₁, —S—C₁₋₁₀-alkyl, —NH₂, —NHX₁, —NX₁X₂, —NH—COX₁, —COOH, —COORS, —CONH₂, —CONHX₁, —CONX₁X₂, —CO—H, —COX₁, C₃₋₁₀-cycloalkyl, 3-14 membered cycloheteroalkyl, C₆₋₁₄-aryl or a 5-14 membered heteroaryl, with the proviso that neither of R₅, R₆, R₇, and R₈ are alkoxy groups (—OX₁) or at least three or all four of R₅, R₆, R₇, and R₈ are alkoxy groups,
wherein
X₁ and X₂ are each independently C₁₋₁₀-alkyl, C₂₋₁₀-alkenyl, C₂₋₁₀-alkynyl, C₃₋₁₀-cycloalkyl, C₅₋₁₀-cycloalkenyl, 3-14 membered cycloheteroalkyl, C₆₋₁₄-aryl and 5-14 membered heteroaryl, and
n is an integer from 2 to 1000.

2. The polymer of claim 1, wherein R₁ and R₂ are each independently C₁₋₃₀-alkyl, C₂₋₃₀-alkenyl or C₂₋₃₀-alkynyl.

3. The polymer of claim 2, wherein C₁₋₃₀-alkyl, C₂₋₃₀-alkenyl or C₂₋₃₀-alkynyl are substituted with 1 to 6 groups independently selected from halogen, —CN, —NO₂, —OH, C₁₋₁₀-alkoxy, —O—CH₂CH₂O—C₁₋₁₀-alkyl, —O—COX₁, —S—C₁₋₁₀-alkyl, —NH₂, —NHX₁, —NX₁X₂, —NH—COX₁, —COOH, —COORS, —CONH₂, —CONHX₁, —CONX₁X₂, —CO—H, —COX₁, C₃₋₁₀-cycloalkyl, 3-14 membered cycloheteroalkyl, C₆₋₁₄-aryl or a 5-14 membered heteroaryl,
wherein
X₁ and X₂ are each independently C₁₋₁₀-alkyl, C₂₋₁₀-alkenyl, C₂₋₁₀-alkynyl, C₃₋₁₀-cycloalkyl, C₅₋₁₀-cycloalkenyl, 3-14 membered cycloheteroalkyl, C₆₋₁₄-aryl and 5-14 membered heteroaryl.

4. The polymer of claim 1, wherein R₁ and R₂ are each independently C₃₋₁₀-cycloalkyl, C₅₋₁₀-cycloalkenyl, or 3-14 membered cycloheteroalkyl.

5. The polymer of claim 4, wherein C₃₋₁₀-cycloalkyl, C₅₋₁₀-cycloalkenyl, or 3-14 membered cycloheteroalkyl are substituted with 1 to 6 groups independently selected from halogen, —CN, —NO₂, —OH, C₁₋₁₀-alkoxy, —O—CH₂CH₂O—C₁₋₁₀-alkyl, —O—COR₇, —S—C₁₋₁₀-alkyl, —NH₂, —NHX₁, —NX₁X₂, —NH—COX₁, —COOH, —COORS, —CONH₂, —CONHX₁, —CONX₁X₂, —CO—H, —COX₁, C₁₋₁₀-alkyl, C₂₋₁₀-alkenyl, C₂₋₁₀-alkynyl, C₆₋₁₄-aryl or a 5-14 membered heteroaryl,
wherein
X₁ and X₂ are each independently C₁₋₁₀-alkyl, C₂₋₁₀-alkenyl, C₂₋₁₀-alkynyl, C₃₋₁₀-cycloalkyl, C₅₋₁₀-cycloalkenyl, 3-14 membered cycloheteroalkyl, C₆₋₁₄-aryl and 5-14 membered heteroaryl.

6. The polymer of claim 1, wherein R₁ and R₂ are each independently C₆₋₁₄-aryl or 5-14 membered heteroaryl.

7. The polymer of claim 6, wherein, C₆₋₁₄-aryl or 5-14 membered heteroaryl are substituted with 1 to 6 groups independently selected from the group consisting of halogen, —CN, —NO₂, —OH, C₁₋₁₀-alkoxy, —O—CH₂CH₂O—C₁₋₁₀-alkyl, —O—COX₁, —S—C₁₋₁₀-alkyl, —NH₂, —NHX₁, —NX₁X₂, —NH—COX₁, —COOH, —COORS, —CONH₂, —CONHX₁, —CONX₁X₂, —CO—H, —COX₁, C₁₋₁₀-alkyl, C₂₋₁₀-alkenyl, C₂₋₁₀-alkynyl, C₃₋₁₀-cycloalkyl, C₅₋₁₀-cycloalkenyl or a 3-14 membered cycloheteroalkyl,
wherein
X₁ and X₂ are each independently C₁₋₁₀-alkyl, C₂₋₁₀-alkenyl, C₂₋₁₀-alkynyl, C₃₋₁₀-cycloalkyl, C₅₋₁₀-cycloalkenyl, 3-14 membered cycloheteroalkyl, C₆₋₁₄-aryl and 5-14 membered heteroaryl.

8. The polymer of claim 1, wherein R₁ and R₂ are both branched alkyl groups selected from the group consisting of 2-ethylhexyl, 2-octyldodecyl, or 2-decyltetradecyl or wherein R₁ and R₂ are both branched alkyl groups having the following formula:

[chemical structure]

9. The polymer of claim 8, wherein each of R₃, R₄, R₉, and R₁₀ are each hydrogen.

10. The polymer of claim 1, wherein each of R₅, R₆, R₇, and R₈ are each hydrogen.

11. The polymer of claim 1, wherein n is an integer from 2 to 100.

12. The polymer of claim 11, wherein n is an integer from 2 to 20.

13. The polymer of claim 1, wherein the polymer is an n-type semi-conductive polymer.

14. The polymer of claim 13, wherein the polymer is modified with a dopant so as to enhance its n-type properties.

15. The polymer of claim 1, wherein the polymer is the reaction product of formula (I) with formula (II): [chemical structure]
wherein
R₁₁ is a halogen selected from the group consisting of fluorine, chlorine, bromine iodine, and astatine, and
R₁₂ and R₁₃ are each independently a linking group.

16. The polymer of claim 15, wherein the linking group is a C₂₋₆alkyl or alkylene group.

17. The polymer of claim 16, wherein the linking group is 2,3-dimethylbutane.

18. The polymer of claim 1 comprised in a photoactive layer of a photovoltaic cell.

19. The polymer of claim 1 comprised in a solution, wherein the polymer is dissolved in the solution.

20. The polymer of claim 1 comprised in an electronic device.

21. The polymer of claim 20, wherein the electronic device is a polymeric organic light-emitting diode (PLED), an organic integrated circuits (O-IC), an organic field effect transistor (OFET), an organic thin film transistor (OTFT), an organic solar cell (O-SC), an organic light emitting diode (OLED), or an organic laser diode (O-laser).

22. A process for making a photoactive layer on a substrate, wherein the photoactive layer comprises the polymer of claim 1, the process comprising disposing the solution of claim 28 on the substrate and drying said solution to form the photoactive layer.

23. A process of making the polymer of claim 1 comprising reacting formula (I) with formula (II) in the presence of a transition metal-containing catalyst, wherein formula (I) and formula (II) have the following structures: [chemical structure]
